(19) United States
(12) Patent Application Publication
(10) Pub. No.: US 2006/0054280 A1
(43) Pub. Date: Mar. 16, 2006

(54) Apparatus of manufacturing display substrate and showerhead assembly equipped therein

(76) Inventor: Geun-Ha Jang, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/066,702

(22) Filed: Feb. 23, 2005

(30) Foreign Application Priority Data
Feb. 23, 2004 (KR) 10-2004-0011910
Feb. 16, 2005 (KR) 10-2005-0012546

(51) Int. Cl. C23F 1/00; C23C 16/00

(52) U.S. Cl. 156/345.34; 118/715

(57) ABSTRACT

A showerhead assembly for used in a manufacturing apparatus for a display substrate is provided in the present invention. The showerhead assembly includes a backing plate having a gas inflow, a showerhead having a plurality of gas injection holes, a plurality of first connectors connecting the showerhead and the backing plate at edge portions thereof, and a plurality of second connectors connecting the showerhead and the backing plate in middle portions thereof.

This application claims the benefit of Korean Patent Applications Nos. 2004-0011910 and 2005-0012546 filed on Feb. 23, 2004 and Feb. 16, 2005, respectively, which are hereby incorporated by reference.

### BACKGROUND OF THE INVENTION

1. Field of the Invention

The present invention relates to a manufacturing apparatus for a display substrate, and more particularly to a showerhead assembly which has a structure preventing heat deflection of showerhead.

2. Discussion of the Related Art

In general, since flat panel display devices are thin, light weight, and have low power consumption, they are commonly used in portable devices. Among the various types of flat panel display devices, liquid crystal display (LCD) devices are commonly used in PDAs, mobile phones and computer monitors because of their superior resolution, color image display, and display quality.

The LCD devices include upper and lower substrates having electrodes that are spaced apart from and face each other, and a liquid crystal material is interposed there between. Accordingly, when a voltage is supplied to the electrodes of the upper and lower substrates and when an electric field is induced to the liquid crystal material, an alignment direction of the liquid crystal molecules changes in accordance with the supplied voltage. By controlling the supplied voltage, the LCD devices provide various light transmittances in order to display image data.

The LCD devices are commonly incorporated in office automation (OA) devices and video equipment due to their lightweight, thin design, and low power consumption. Among the different types of LCD devices, active matrix LCDs (AM-LCDs) have thin film transistors and pixel electrodes arranged in a matrix configuration and offer high resolution and superiority in displaying moving images. A typical AM-LCD panel has an upper substrate, a lower substrate, and a liquid crystal material layer interposed there between. The upper substrate, which is commonly referred to as a color filter substrate, includes a common electrode and color filters. The lower substrate, which is commonly referred to as an array substrate, includes switching elements, such as thin film transistors (TFTs), and pixel electrodes. The common and pixel electrodes produce electric fields between them to re-align the liquid crystal molecules.

When forming the array substrate and the color filter substrate, a lot of thin films are usually formed on and over glass substrates. At this time, a thin film deposition process, a photolithography process, a patterning process, a rinsing process and so on are required. The thin film deposition process forms a plurality of thin films, such as conductor films and insulator films, on and over the substrate. The photolithography and patterning processes removes or leaves some portions of the thin film using a photosensitive photoresist so as to pattern the thin films. The rinsing process removes residual impurities by way of washing and drying.

Each of the above-mentioned processes is conducted in a process chamber where a process atmosphere is optimized. Especially, the process chamber may provide with Plasma Enhanced Chemical Vapor Deposition (PECVD), Dry Etch, etc.

In the meantime, internal temperature of the process chamber is highly increased to produce plasmas during the deposition or etching process to the substrate. For example, when the plasma is generated inside the process chamber, the temperature may reach about 300 to 400 degrees Celsius that is enough to deflect internal elements of the process chamber. Namely, due to the high internal temperature greater than the heat deflection temperature, the internal structure, e.g., a showerhead may get stressed and heat-deflected.

### SUMMARY OF THE INVENTION

Accordingly, the present invention is directed to a manufacturing apparatus for a substrate, which substantially obviates one or more of the problems due to limitations and disadvantages of the related art.

An advantage of the present invention is to provide a showerhead assembly, which enhances manufacturing yields and productivities.

Another advantage of the present invention is to provide a manufacturing apparatus for a substrate, which prevents heat deflection of showerhead.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

In order to achieve the above object, the preferred embodiment of the present invention provides a showerhead assembly for used in a manufacturing apparatus for a display substrate. The showerhead assembly includes a backing plate having a gas inflow; a showerhead having a plurality of gas injection holes; a plurality of first connectors connecting the showerhead and the backing plate at edge portions thereof; and a plurality of second connectors connecting the showerhead and the backing plate in middle portions thereof.

According to the present invention, the gas inflow is formed in the middle of the backing plate and the plurality of second connectors are disposed around the gas inflow. The first and second connectors are one of screws and bolts.

The showerhead assembly of the present invention further includes a sealing cap on the backing plate to cover a head of each second connector, and a sealant between the sealing cap and the backing plate. The sealant may an O-ring.

In the present invention, the second connectors penetrate the backing plate and are screwed to the middle portion of the showerhead. The showerhead assembly further includes a rubbery O-ring between the backing plated and a head of each second connector and a washer between the rubbery O-ring and the head of each second connector.

The showerhead assembly further includes an O-ring on the backing plate around a head of each second connector, and a sealing plate covering the O-ring and the head of each second connector, wherein the sealing plate is fastened to the backing plate by a plurality of screws.

The showerhead assembly further includes a first O-ring around the gas inflow and a second O-ring around the first O-ring, wherein the second connectors are disposed between the first and second O-rings around the gas inflow. The showerhead assembly further includes a sealing plate covering the first and second O-rings and the second connectors, wherein the sealing plate is fastened to the backing plate by a plurality of first and second screws, wherein the plurality of first screws are disposed between the gas inflow and the first O-ring, and wherein the plurality of second screws are disposed in edge portions of the sealing plate outside the second O-ring.

Additionally, in the showerhead assembly of the present invention, each of the second connectors is integrally formed with the showerhead, and wherein each second connector extends from the showerhead to penetrate the backing plate and is screwed into a nut. The showerhead assembly further includes a rubbery O-ring between the backing plated and the nut and a washer between the rubbery O-ring and the nut.

The showerhead assembly further includes an O-ring on the backing plate around the nut and a sealing plate covering the O-ring and the nut, wherein the sealing plate is fastened to the backing plate by a plurality of screws.

The showerhead assembly further includes a first O-ring around the gas inflow and a second O-ring around the first O-ring, wherein the second connectors and the nuts are disposed between the first and second O-rings around the gas inflow. Also, the showerhead assembly further includes a sealing plate covering the first and second O-rings and the nuts, wherein the sealing plate is fastened to the backing plate by a plurality of first and second screws, wherein the plurality of first screws are disposed between the gas inflow and the first O-ring, and wherein the plurality of second screws are disposed in edge portions of the sealing plate outside the second O-ring.

In another aspect, the present invention provides an apparatus of forming a display substrate. The apparatus includes a process chamber accommodating a susceptor, a gas inflow pipe over the susceptor, a backing plate having a gas inflow corresponding to the gate inflow pipe, a showerhead disposed adjacent to the backing plate, the showerhead having a plurality of gate injection holes, a first connector connecting the showerhead and the backing plate at an edge portion thereof, and a second connector connecting the showerhead and the backing plate in a middle portion thereof.

In the apparatus according to the present invention, the process chamber includes a chamber body and an upper cover that are coupled together to form an airtight space therein, and wherein the upper cover have a gas inflow corresponding to the gate inflow pipe.

Additionally, the apparatus further includes an insulator between the upper cover and the backing plate, and O-rings on top and bottom surfaces of the insulators. Moreover, the apparatus according to the present invention further includes a baffle between the shower head and the backing plate, wherein the second connector is one of screw and bolt and penetrates the baffle and the backing plate.

It is to be understood that both the foregoing general description and the following detailed description are exemplary and explanatory and are intended to provide further explanation of the invention as claimed.

### BRIEF DESCRIPTION OF THE DRAWING

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a schematic cross sectional view showing an exemplary apparatus for manufacturing a substrate;

FIG. 2 is an enlarged schematic sectional view showing a showerhead after the heat deflection;

FIG. 3 is a schematic cross sectional view illustrating an apparatus for manufacturing a display substrate according to a principle of the present invention;

FIG. 4 is an enlarged cross sectional view illustrating the second connectors of FIG. 3;

FIG. 5 is an enlarged cross sectional view illustrating another exemplary second connectors of FIG. 3;

FIG. 6 is a cross sectional view illustrating an exemplary sealing-up method around the second connector;

FIG. 7 is a top plan view illustrating another exemplary sealing-up method using a sealing plate; and

FIG. 8 is a top plan view illustrating another exemplary sealing-up method using a sealing plate and two sealants.

### DETAILED DESCRIPTION OF THE PREFERRED EMBODIMENTS

Reference will now be made in detail to the preferred embodiments of the present invention, examples of which are illustrated in the accompanying drawings. Wherever possible, the same reference numbers will be used throughout the drawings to refer to the same or like parts.

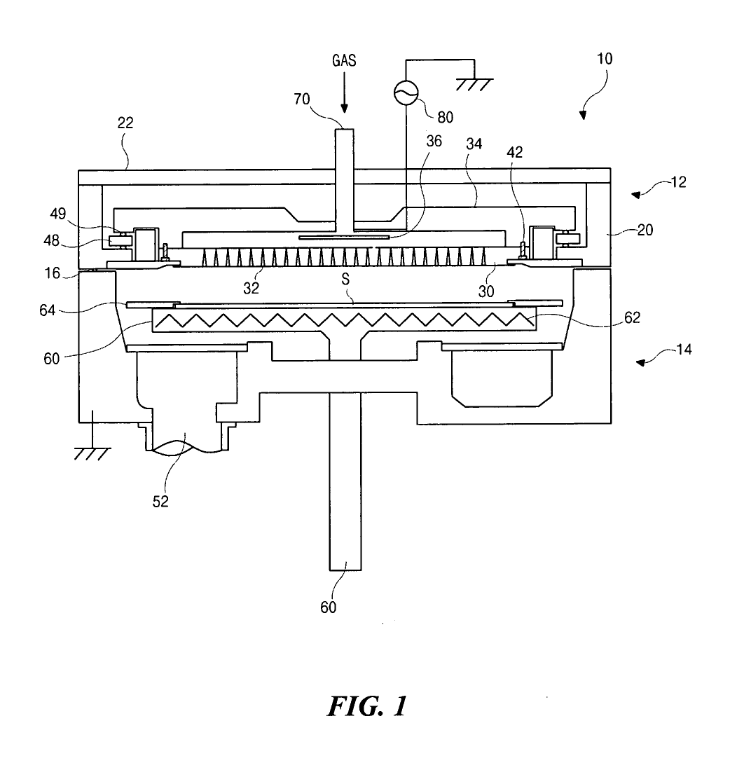

FIG. I is a schematic cross sectional view showing an exemplary manufacturing apparatus for a substrate. The manufacturing apparatus for a substrate is commonly referred to as a process chamber 10 that has airtight space therein. The thin film process, such as deposition or etching, is performed in that airtight space. As shown in FIG. 1, the process chamber 10 includes an upper cover 12 and a chamber body 14 that are coupled together to form the space for the thin film process. An O-ring 16 is interposed between the upper cover 12 and the chamber body 14 in order to make the inner space airtight.

The upper cover 12 is consisting of a side lid 20 and a top lid 22 that are bonded together. A backing plate 34 is located underneath the top lid 22, and a showerhead 30 is located underneath the backing plate 34. The backing plate 34 and the showerhead 30 are coupled at their edges by connectors 42, for example, screws or bolts. The side lid 20 surrounds the sides of the backing plate 34 and the showerhead 30 such that the side and top lids 20 and 22 accommodate and completely cover the backing plate 34 and the showerhead 30. The top lid 22 and the backing plate 34 have holes in their central portions, respectively, and a gas inflow pipe 70 passes through such holes to supply process gasses into the airtight space of the process chamber 10. Although not shown in FIG. 1, the gas inflow pipe 70 is connected to a gas line that extends from a gas source. A baffle 36 is disposed at the end of the gas inflow pipe 70 between the showerhead 30 and the backing plate 34. The showerhead 30 includes a lot of injection holes 32 to distribute the process gases over a substrate S. The process gases supplied through the gas inflow pipe 70 are first distributed by the baffle 36 and then they are injected over the substrate S by the injection holes 32 of the showerhead 30. An RF power source 80 is electrically connected to both the backing plate 34 and the showerhead 30 in order to supply energy to them, such that the process gases injected by the showerhead 30 are excited and then converted into plasma to deposit or etch thin films. Namely, the backing plate 34 and the showerhead 30 function as a electrode during the plasma process.

As mentioned before, the chamber body 14 is coupled with the upper cover 12. Specifically, a side wall of the chamber body 14 is connected to the side lid 20 of the upper cover 12 with the O-ring 16 interposed there between. Inside the chamber body 14, there is a susceptor 60 on which the substrate S is laid. The susceptor 60 is spaced apart from and corresponds to the showerhead 30. In addition, the susceptor 60 includes a heater 62 therein in order to supply heat to the substrate S during the process, such that the susceptor 60 functions as an opposite electrode during the plasma process. On the susceptor 60, shadow frames 64 are formed to hold the substrate S. Further, there is an exhauster 52 at the bottom of the chamber body 14 in order to discharge waste and residual gases out of the process chamber 10 after the plasma process.

Still in FIG. 1, an insulator 48 is interposed between the backing plate 34 and the side lid 20 so as to electrically isolate the upper cover 12 from the backing plate 34 and showerhead 30. Additionally, packing materials 49, e.g., O-rings, are disposed on top and bottom surfaces of the insulator 48. The packing materials 49 prevent the process gases from flowing outside. In the meantime, the manufacturing apparatus for the display substrate is enormous with great volume because the substrate processed therein is becoming enlarged in these days. Therefore, the showerhead 30 has large size. However, such large showerhead 30 may have some disadvantages. For example, the airtight space of the process chamber 10 may have a high temperature of 300 to 400 degrees Celsius during the plasma process because the heater 62 in the susceptor 60 supplies heat for the plasma process. Further, such high temperature causes the thermal expansion to the structural elements (e.g., the showerhead 30). Therefore, the showerhead 30 may be deflected, i.e., the heat deflection. The larger the showerhead becomes, the more the heat deflection increases.

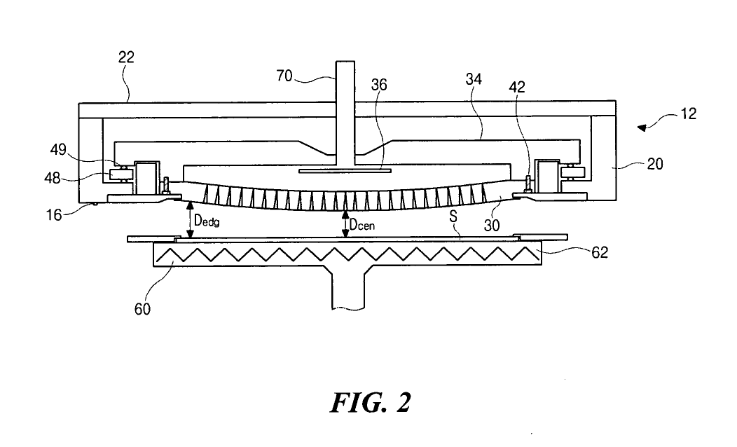

FIG. 2 is an enlarged schematic sectional view showing a showerhead after the heat deflection. As shown in FIG. 2, the showerhead 30 is expanded by the heat applied by the heater 62, and thus the center portion of the showerhead 30 droops. Thus, a central distance Dcen between the showerhead 30 and substrate S is shortened rather than an edge distance Dedg. Such different distances between the central portion and the edge portion cause the non-uniform generation of plasma. Therefore, the substrate may have a thin film having rough surface, and the thin film on the substrate may be irregularly etched.

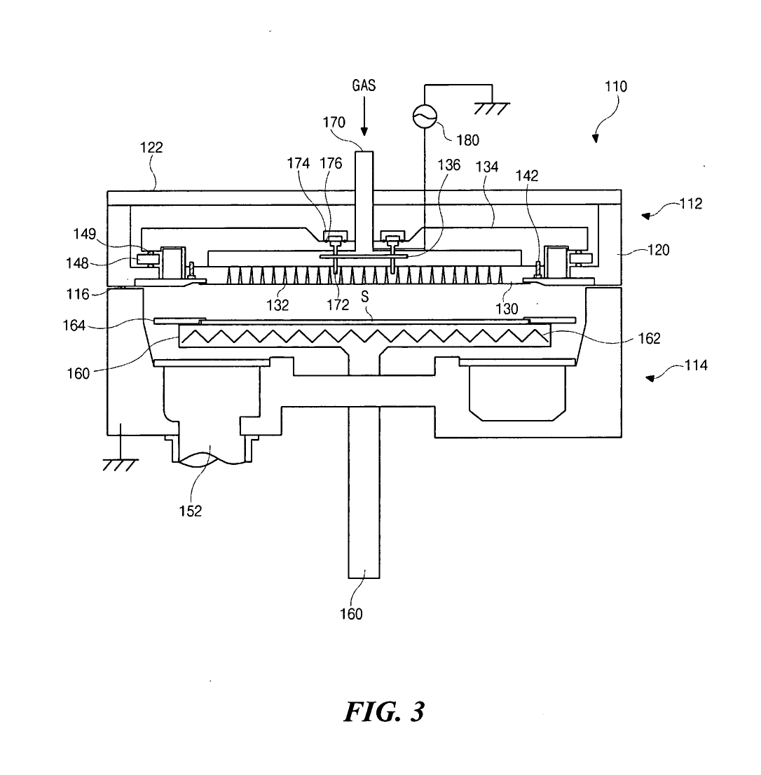

FIG. 3 is a schematic cross sectional view illustrating a manufacturing apparatus for a substrate according to a principle of the present invention. Although the manufacturing apparatus of FIG. 3 is quite similar to that of FIG. 1, it has different structure according to the present invention.

In FIG. 3, the manufacturing apparatus commonly referred to as a process chamber 110 has airtight space therein in which the thin film process, such as deposition or etching, is performed. The process chamber 110 includes an upper cover 112 and a chamber body 114 that are coupled together to form the space for the thin film process. An O-ring 116 is interposed between the upper cover 112 and the chamber body 114 in order to make the inner space airtight.

The upper cover 112 is consisting of a side lid 120 and a top lid 122 that are bonded together. A backing plate 134 is located underneath the top lid 122, and a showerhead 130 is located underneath the backing plate 134. The backing plate 134 and the showerhead 130 are coupled at their edges by first connectors 142, for example, screws or bolts. The side lid 120 surrounds the sides of the backing plate 134 and the showerhead 130 such that the side and top lids 120 and 122 accommodate and completely cover the backing plate 134 and the showerhead 130. The top lid 122 and the backing plate 134 have holes in their central portions, respectively, and a gas inflow pipe 170 passes through these holes to supply process gasses into the airtight space of the process chamber 110. Although not shown in FIG. 3, the gas inflow pipe 170 is connected to a gas line that extends from a gas source. A baffle 136 is disposed at the end of the gas inflow pipe 170 between the showerhead 130 and the backing plate 134. The showerhead 130 includes a lot of injection holes 132 to distribute the process gases over a substrate S. The process gases supplied through the gas inflow pipe 170 are first distributed by the baffle 136, and then they are injected over the substrate S by the injection holes 132 of the showerhead 130. An RF power source 180 is electrically connected to both the backing plate 134 and the showerhead 130 in order to supply electric energy to them, such that the process gases injected by the showerhead 130 are excited and then converted into plasma to deposit or etch thin films. Namely, the backing plate 134 and the showerhead 130 function as a electrode during the plasma process.

Still in FIG. 3, a plurality of second connectors 172 are formed around the gas inflow pipe 170. Each of the plurality of second connectors 172 connects the showerhead 130 to the backing plate 134, especially their central portions. Namely, the second connectors 172 prevent the heat deflection and droop of the showerhead 130 during the plasma process by way of holding the center portion of the showerhead 130.

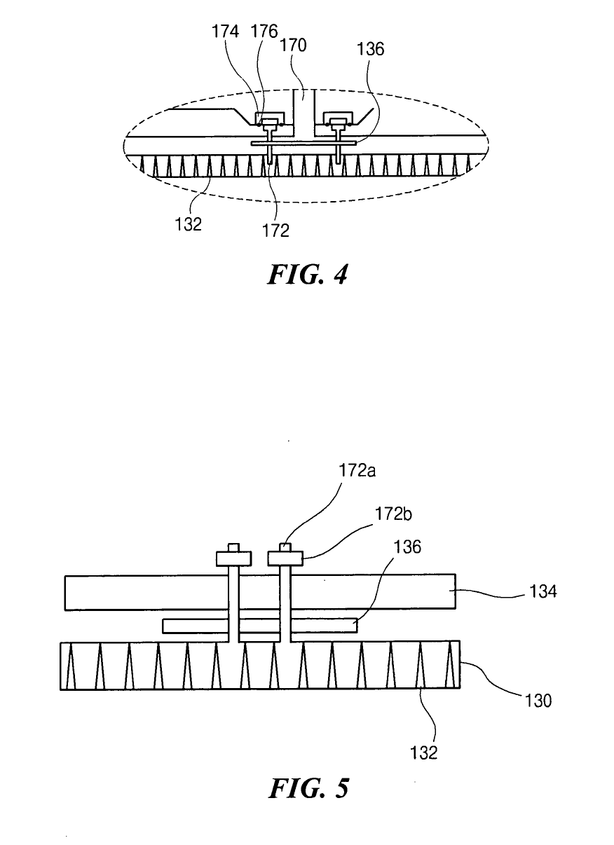

FIG. 4 is an enlarged cross sectional view illustrating the second connectors of FIG. 3. The second connectors 172 penetrate the backing plate 134 and the baffle 136 and then are connected to the showerhead 130. The second connectors 172 may be bolts or screws. A head of each second connector 172 is disposed on top surface of the backing plate 134, and a tale of each second connector 172 may be screwed into the showerhead 130.

However, each of the second connectors 172 may include bolt 172a and nut 172b as shown in FIG. 5. In addition, the bolt 172a may be integrated with the showerhead 130. When the bolt 172a is formed as one body with the showerhead 130, it penetrates the baffle 136 and the backing plate 134 and then fastened with the nuts 172b.

Now referring to FIG. 4, a sealing cap 174 may be disposed overlapping the head of each second connector 172. Furthermore, a sealant 176, for example, O-ring, may be formed between the backing plate 134 and the sealing cap 174. Those sealing cap 174 and sealant 176 prevent air ventilation that may be caused in the hole formed through the backing plate 134 for the second connector 172.

Now referring back to FIG. 3, the chamber body 114 is coupled with the upper cover 112. Specifically, a sidewall of the chamber body 114 is connected to the side lid 120 of the upper cover 112 with the O-ring 116 interposed there between. Inside the chamber body 114, there is a susceptor 160 on which the substrate S is laid. The susceptor 160 is spaced apart from and corresponds to the showerhead 130. In addition, the susceptor 160 includes a heater 162 therein in order to supply heat to the substrate S during the process, such that the susceptor 160 functions as an opposite electrode during the plasma process. On the susceptor 160, shadow frames 164 are formed to hold the substrate S. Further, there is an exhauster 152 at the bottom of the chamber body 114 in order to discharge waste and residual gases out of the process chamber 110 after the plasma process.

Still in FIG. 3, an insulator 148 is interposed between the backing plate 134 and the side lid 120 so as to electrically isolate the upper cover 112 from the backing plate 134 and showerhead 130. Additionally, packing materials 149, e.g., O-rings, are disposed on top and bottom surfaces of the insulator 148. The packing materials 149 prevent the process gases from flowing outside.

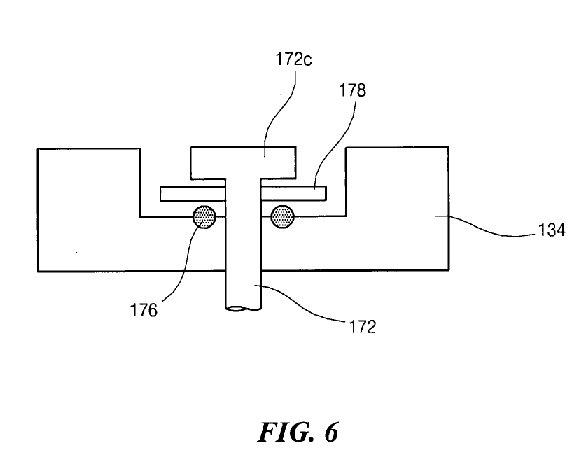

In the meanwhile, it is possible to modify and vary the aforementioned second connector 172 and the sealing method. Hereinafter, the exemplary modification and variation will be explained with reference to FIGS. 6-8.

FIG. 6 is a cross sectional view illustrating an exemplary sealing-up method around the second connector. As shown, the backing plate 134 has a hole, and then the second connector 172 penetrates that hole to be connected to the showerhead 130 as described with reference to FIGS. 3-5. The second connector 172 has a head portion 172c that may be a nut or a bolt or screw head. A sealant 176, e.g., O-ring, is disposed between the backing plate 134 and the head portion 172c of second connector 172 in order to prevent the air ventilation caused in the hole of the backing plate 134. Between the sealant 176 and the head portion 172c, a washer 178 is interposed to tightly fasten the sealant 176 and to prevent the sealant breakdown and the damage of backing plate 134. Since the sealant 176 and the washer 178 are interposed between the backing plate 134 and the head portion 172c of second connector 172, the air streaming, which may be caused through the hole formed in the backing plate 134 for the second connector 172, is completely prevented. If the washer 178 is adopted, the sealing cap 174 may not be omitted.

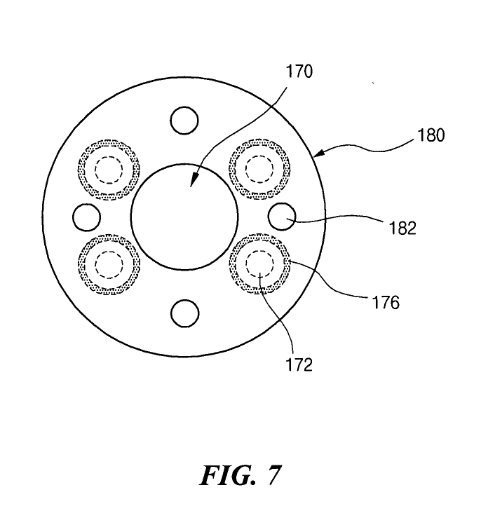

FIG. 7 is a top plan view illustrating another exemplary sealing-up method using a sealing plate. As shown, the plurality of second connectors 172 that fasten the showerhead to the backing plate are disposed around the gas inflow pipe 170. A sealant 176 is disposed around each second connector 172. The sealant 176 is an O-ring, for example, which is formed of a rubbery material. A sealing plate 180 is placed over the second connectors 172 and the sealants 176, and fastened to the underlying backing plate (reference 134 of FIG. 3) by a plurality of screws or bolts 182. Thus, the sealing plate 180 tightly presses and holds the underlying sealants 172.

In FIG. 7, since the rubbery sealant 176 is disposed around each second connector 172 and then the sealing plate 178 is over the sealant 176, the air streaming that may be caused in the holes formed in the backing plate for the second connectors 176 is absolutely prevented. Accordingly, the process chamber (reference 110 of FIG. 3) is able to maintain airtight vacuum condition therein during the plasma process. The sealing plate 180 functions as a sealing cap of FIG. 4.

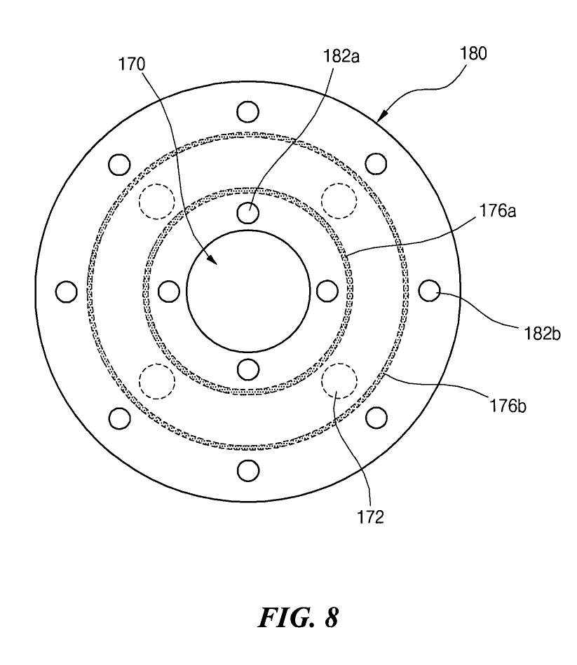

FIG. 8 is a top plan view illustrating another exemplary sealing-up method using a sealing plate. As shown, the plurality of second connectors 172 that fasten the showerhead to the backing plate are disposed around the gas inflow pipe 170. A first sealant 176a is also disposed around the gas inflow pipe 170 in a position close to the gas inflow pipe rather than the second connectors 172. A second sealant 176b is disposed around the second connectors 172. Namely, the second connectors 172 are disposed between the first and second sealants 176a and 176b. The first and second sealants 176 are O-rings, for example, which are formed of rubbery material.

Still in FIG. 8, a sealing plate 180 is disposed over the second connectors 172 and the first and second sealants 176a and 176b. A plurality of first and second screws (or bolts) 182a and 182b strongly fasten the sealing plate 180 to the underlying backing plate (reference 134 of FIG. 3). The first screws 182a are disposed between the gas inflow pipe 170 and the first sealant 176a, and the second screws 182b are disposed in edge portions of the sealing plate 180 outside the second sealant 176b. Since the first and second sealants 176a and 176b keep the second connectors in isolation and since the sealing plate 180 presses the first and second sealants 176a and 176b over the second connectors 172, the air streaming that may be caused in the holes formed in the backing plate for the second connectors 176 is absolutely prevented. Accordingly, the process chamber (reference 110 of FIG. 3) is able to maintain airtight vacuum condition therein during the plasma process.

According to the present invention, although the internal temperature of the process chamber highly increases up to more than 300 to 400 degrees Celsius, the showerhead is not deflected by that high temperature because the first and second connectors hold and connect the showerhead to the backing plate. Therefore, the plasma process can be performed all over the substrate. Moreover, since the sealants and sealing cap and plate are adopted around the second connectors in the present invention, the air streaming and ventilation that may be caused in the holes for the second connectors is absolutely prevented. Accordingly, more safe and reliable display substrates can be produced when the present invention is utilized.

It will be apparent to those skilled in the art that various modifications and variation can be made in the present invention without departing from the spirit or scope of the invention. Thus, it is intended that the present invention covers the modifications and variations of this invention provided they come within the scope of the appended claims and their equivalents.

What is claimed is:

1. A showerhead assembly for used in a manufacturing apparatus for a display substrate, comprising:
a backing plate having a gas inflow;
a showerhead having a plurality of gas injection holes;
a plurality of first connectors connecting the showerhead and the backing plate at edge portions thereof; and
a plurality of second connectors connecting the showerhead and the backing plate in middle portions thereof.

2. The showerhead assembly according to claim 1, wherein the gas inflow is formed in the middle of the backing plate and the plurality of second connectors are disposed around the gas inflow.

3. The showerhead assembly according to claim 1, wherein the first and second connectors are one of screws and bolts.

4. The showerhead assembly according to claim 1, further comprising a sealing cap on the backing plate to cover a head of each second connector.

5. The showerhead assembly according to claim 4, further comprising a sealant between the sealing cap and the backing plate.

6. The showerhead assembly according to claim 5, wherein the sealant is an O-ring.

7. The showerhead assembly according to claim 1, wherein the second connectors penetrate the backing plate and are screwed to the middle portion of the showerhead.

8. The showerhead assembly according to claim 7, further comprising a rubbery O-ring between the backing plated and a head of each second connector and a washer between the rubbery O-ring and the head of each second connector.

9. The showerhead assembly according to claim 7, further comprising an O-ring on the backing plate around a head of each second connector, and a sealing plate covering the O-ring and the head of each second connector, wherein the sealing plate is fastened to the backing plate by a plurality of screws.

10. The showerhead assembly according to claim 7, further comprising a first O-ring around the gas inflow and a second O-ring around the first O-ring, wherein the second connectors are disposed between the first and second O-rings around the gas inflow.

11. The showerhead assembly according to claim 10, further comprising a sealing plate covering the first and second O-rings and the second connectors, wherein the sealing plate is fastened to the backing plate by a plurality of first and second screws, wherein the plurality of first screws are disposed between the gas inflow and the first O-ring, and wherein the plurality of second screws are disposed in edge portions of the sealing plate outside the second O-ring.

12. The showerhead assembly according to claim 1, wherein each of the second connectors is integrally formed with the showerhead, and wherein each second connector extends from the showerhead to penetrate the backing plate and is screwed into a nut.

13. The showerhead assembly according to claim 12, further comprising a rubbery O-ring between the backing plated and the nut and a washer between the rubbery O-ring and the nut.

14. The showerhead assembly according to claim 12, further comprising an O-ring on the backing plate around the nut and a sealing plate covering the O-ring and the nut, wherein the sealing plate is fastened to the backing plate by a plurality of screws.

15. The showerhead assembly according to claim 12, further comprising a first O-ring around the gas inflow and a second O-ring around the first O-ring, wherein the second connectors and the nuts are disposed between the first and second O-rings around the gas inflow.

16. The showerhead assembly according to claim 15, further comprising a sealing plate covering the first and second O-rings and the nuts, wherein the sealing plate is fastened to the backing plate by a plurality of first and second screws, wherein the plurality of first screws are disposed between the gas inflow and the first O-ring, and wherein the plurality of second screws are disposed in edge portions of the sealing plate outside the second O-ring.

17. An apparatus of forming a display substrate, comprising:
a process chamber accommodating a susceptor;
a gas inflow pipe over the susceptor;
a backing plate having a gas inflow corresponding to the gate inflow pipe;
a showerhead disposed adjacent to the backing plate, the showerhead having a plurality of gate injection holes;
a first connector connecting the showerhead and the backing plate at an edge portion thereof; and
a second connector connecting the showerhead and the backing plate in a middle portion thereof.

18. The apparatus according to claim 17, wherein the process chamber includes a chamber body and an upper cover that are coupled together to form an airtight space therein, and wherein the upper cover have a gas inflow corresponding to the gate inflow pipe.

19. The apparatus according to claim 18, further comprising an insulator between the upper cover and the backing plate, and O-rings on top and bottom surfaces of the insulators.

20. The apparatus according to claim 17, further comprising a baffle between the shower head and the backing plate, wherein the second connector is one of screw and bolt and penetrates the baffle and the backing plate.
